(19) United States
(12) Patent Application Publication
(10) Pub. No.: US 2012/0086460 A1
(43) Pub. Date: Apr. 12, 2012

(54) SYSTEM AND METHOD FOR OPERATING MONITORING ELEMENTS AND SINGLE USE ELEMENTS WITH A COMMON CABLE

(75) Inventor: James J. Freeman, Houston, TX (US)

(73) Assignee: BAKER HUGHES INCORPORATED, Houston, TX (US)

(21) Appl. No.: 12/902,323

(22) Filed: Oct. 12, 2010

(51) Int. Cl. G01R 31/02

(52) U.S. Cl. 324/543

(57) ABSTRACT

A system includes a common line configured to conduct electrical power and one or more monitoring devices coupled to the common line and configured to operate when a positive voltage is provided on the common line. The system also includes a single use device coupled to the common line and an activation circuit coupled between the single use device and the common line, the activation circuit only allowing current to flow through the single use device when a negative voltage is provided on the common line.

### BACKGROUND

The process of extracting a natural resource from the earth includes many stages including a drilling stage, casing stage and completion stage. During the completion stage, elements such as expansion bridges are placed in the borehole and expanded to define production regions.

Monitoring elements such as gauges are typically permanently or semi-permanently positioned in the production regions of a completed well. The gauges are typically connected in parallel to a single conductor cable that supplies both power to and communication with the gauges. It shall be understood that it is desirable to keep the number of cables traveling from the surface to the production region(s) to a minimum.

### SUMMARY

According to one embodiment, a system that includes a common line configured to conduct electrical power is provided. The system of this embodiment also includes one or more monitoring devices coupled to the common line and configured to operate when a positive voltage is provided on the common line and a single use device coupled to the common line. The system of this embodiment also includes an activation circuit coupled between the single use device and the common line, the activation circuit only allowing current to flow through the single use device when a negative voltage is provided on the common line.

According to another embodiment, a method comprising coupling one or more monitoring devices coupled to a common line, the one or more monitoring devices configured to operate when a positive voltage is provided on the common line; a first activation circuit to the common line; and coupling a first single use device to the first activation circuit such that a current from the first single use device to the common line when a negative voltage is provided on the common line is disclosed.

### BRIEF DESCRIPTION OF THE DRAWINGS

Referring now to the drawings wherein like elements are numbered alike in the several Figures:

FIG. 1 is a representation of a system according to one embodiment of the present invention;

FIG. 2 is a circuit diagram showing an activation circuit according to one embodiment;

FIG. 3 is a circuit diagram showing an activation circuit according to another embodiment; and

FIG. 4 is circuit diagram showing multiple different activation circuits coupled to a common line.

### DETAILED DESCRIPTION

As discussed above, in some cases it may be preferable to keep the number of the cables that travel from the surface to a production region located below the earth's surface to a minimum. As also discussed above, gauges are typically provided in the production region and include a cable that provides power to them and allows the gauges to communicate to devices located at the surface.

In one embodiment of the present invention, one or more other devices are coupled to the cable in such a manner that they do not interfere with the operation of or communication with the gauges. In one embodiment, the other devices are single use elements. A single use device is a device that after being activated does not need to receive additional power or be communicated with. An example of such a single use element is an expansion bridge plug used in a cased hole. In operation, an expansion bridge plug receives power and is caused to expand within a borehole to seal portions of the borehole from other portions. After the expansion bridge plug has been expanded, there is no longer a need to provide power or other communication with it.

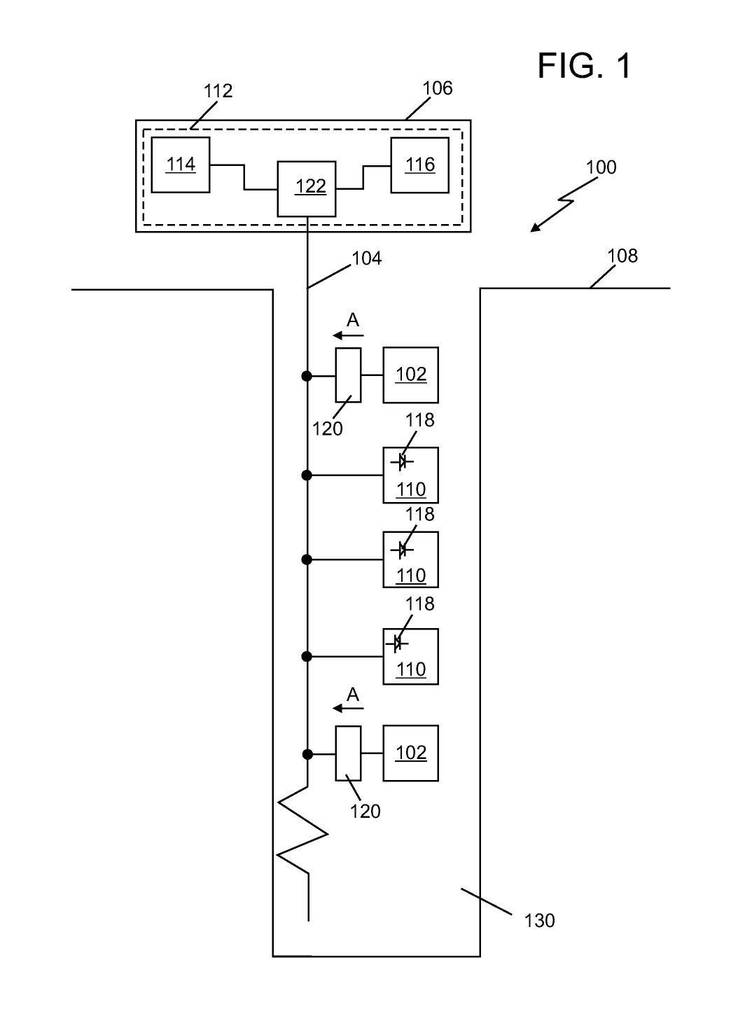

FIG. 1 shows a system 100 that includes a plurality of single use devices 102 to be coupled to common communication/power line 104 (common line 104). In one embodiment, the system 100 may only include one single use device 102 coupled to it. As illustrated, the single use devices 102 are still electrically coupled to the common line 104. The common line 104 is coupled to a surface electronics 106 that are located above the earth's surface 108 in one embodiment. The surface electronics 106 could be located in a pod on the sea floor or other location in one embodiment.

The common line 104 is also coupled to one or more monitoring devices 110. The common line 104 carries power from the surface electronics 106 to the monitoring devices 110. In one embodiment, the common line 104 also allows for communication between the surface electronics 106 and the monitoring devices 110. The communication can be unidirectional from the monitoring devices 110 to the surface electronics 106 or bidirectional between the monitoring devices 110 to the surface electronics 106. In one embodiment, the common line 104 is a tubing encased conductor (TEC). In one embodiment, the monitoring devices 110 are gauges. In particular, the monitoring devices 110 can be any of: a temperature gauge, a pressure gauge, a vibration gauge, a flow rate gauge, or any other type of gauge or monitoring device that can be utilized in a downhole environment.

In one embodiment, the surface electronics 106 include a power supply 112. In general, the power supply 112 provides a positive voltage/current to the one or more monitoring devices 110. To that end, the power supply 112 is illustrated as including a positive power supply portion 114.

In one embodiment, each of the monitoring devices 110 includes a diode 118 having its anode electrically coupled to the common line 104. In this manner, only a positive voltage can provide a current to the monitoring device 110. Stated differently, in the event that a negative voltage was provided on the common line 104, the negative voltage would not affect the monitoring device 110. It shall be understood that the diode 118 could be outside of the monitoring devices in one embodiment.

In one embodiment, an activation circuit 120 is disposed between the common line 104 and the single use devices 102. Examples of activation circuits 120 are described below. In general, the activation circuits 120 are configured such that they only allow current to flow through the single use devices 102 when the common line 104 presents a negative voltage. To that end, the power supply 112 is illustrated as including negative power supply portion 116. Both the negative power supply 116 and the positive power supply 114 are coupled to a supply selector 122. The supply selector 122 couples either the positive power supply 114 or the negative power supply 116 to the common line 104. Of course, the positive power supply 114 and the negative power supply 116 could be the same power supply. In such a case, the supply selector 122 serves to switch the connection of the common line 104 from one configuration to another such that it presents either a positive or negative voltage to elements coupled thereto.

In operation, the common line 104 and some or all of the monitoring devices 110 and the single use devices 102 are lowered into a borehole 130 that penetrates the surface 108 of the earth. When positioned at the desired position, the negative voltage supply 116 is coupled to the common line 104. The negative voltage supply 116 supplies a negative voltage to the common line 104. As discussed above, the monitoring devices 110 each include diodes 118 that only allow current to flow to or from the monitoring devices 110 when a positive voltage is provided thereto. Thus, at this stage, the monitoring devices 110 are not powered.

In contrast, application of a negative voltage to the common line 104 causes current to flow through the single use devices 102 in the direction shown by arrow A. This current causes the single use devices 102 to actuate. For example, in one embodiment, single use devices 102 are expansion bridge plugs. Supplying about 400 ma to them causes them to actuate and expand and seal the borehole 130. The activation circuit 120 blocks current from flowing in the opposite direction of arrow A. As such, when a positive voltage is provided to the common line 104, the single use devices 102 are electrically isolated from other devices coupled to the common line 104. Of course, in some cases, it may be beneficial to completely remove or increase the electrical isolation of the single use device 102 from the common line 104 after they have been used.

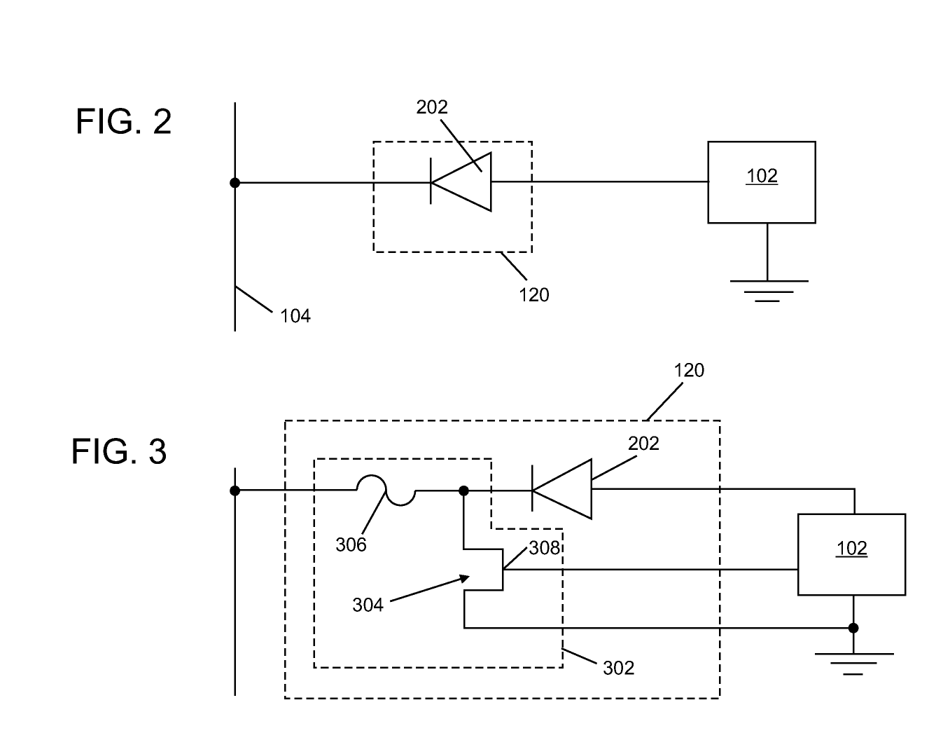

FIG. 2 shows an example of one embodiment of an activation circuit 120 according to one embodiment coupled between a single use device 102 and a common line 104. As shown, the single use device 102 is coupled to ground. In this embodiment, the activation circuit 120 comprises a blocking diode 202. The blocking diode 202 includes an anode coupled to the single use device 102 and a cathode coupled to the common line 104. Application of a positive voltage to the common line 104 does not affect the single use device 102 because the blocking diode 202 blocks the flow of current from the common line 104 to the single use device 102. Of course, the blocking diode 202 may be selected such that it does not breakdown or enter avalanche based on the expected positive voltages applied to the common line 104. Application of a negative voltage to the common line 104 allows current to pass from ground, through the single use device 102, and to the common line 104.

As discussed above, it may be beneficial to electrically isolate the single use device 102 from the common line 104 after the single use device 102 has been actuated. To that end, and as shown in FIG. 3, the activation circuit 120 includes an isolation element 302. In one embodiment, isolation element 302 is formed by a transistor 304 and a fuse 306 serially coupled between ground and the common line 104. When the single use device 102 finishes operating, it provides a gating signal to the gate 308 of the transistor 304. This signal causes the transistor 304 to conduct and, thereby, shorts the single use device 102 out of the activation circuit 120. Shorting the single use device 102 out of the activation circuit 120 increases current through the fuse 306. The increased current through the fuse 306 and causes is to blow. Of course, to this end, the single use device 102 may include a capacitor or other energy storage element that allows is it to provide the gating signal even after it has been shorted out of the activation circuit 120.

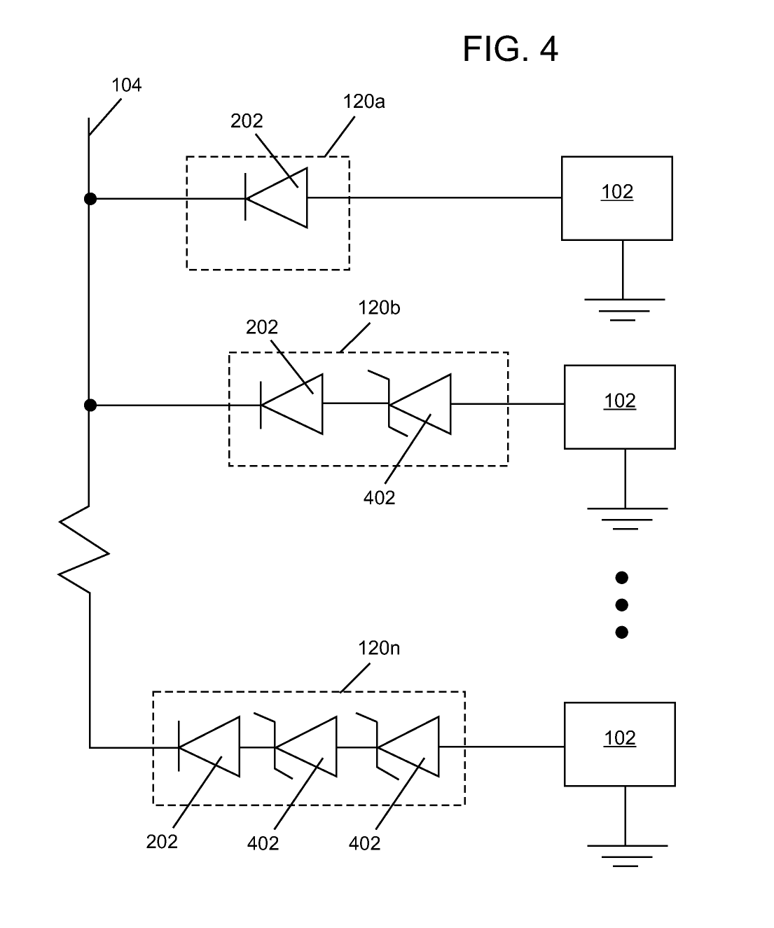

FIG. 4 shows an embodiment of the present invention having multiple single use devices 102 coupled to the common line 104. In this embodiment, multiple different activation circuits 120a . . . 120n are present. In operation, the different activation circuits activate at different voltages. In this manner, different single used devices 102 can be individually activated.

The different activation circuits 120 include, for example, different numbers of zener diodes coupled in series between the common line 104 and the single use devices 102. For example, as illustrated in FIG. 4, a first activation circuit 120a includes zero zener diodes, a second activation circuit 120b includes one zener diode 402 and an nth activation circuit includes n−1 zener diodes 402. The zener diodes 402 are arranged with the same polarity as the blocking diode 120. Application of a first negative voltage causes the first activation circuit 120a to activate and a second negative voltage having a greater magnitude than the first negative voltage causes the second activation circuit 120b to activate and so on. In one embodiment the first and second activation circuits 120a, 120b include the isolation element 302 shown in FIG. 3.

While preferred embodiments have been shown and described, modifications and substitutions may be made thereto without departing from the spirit and scope of the invention. Accordingly, it is to be understood that the present invention has been described by way of illustrations and not limitation. For example, the monitoring device 110 could be operable by the application of a negative voltage, and the activation circuit 120 could be operable by the application of a positive voltage.

1. A system comprising:
a common line configured to conduct electrical power;
one or more monitoring devices coupled to the common line and configured to operate when a positive voltage is provided on the common line;
a single use device coupled to the common line;
an activation circuit coupled between the single use device and the common line, the activation circuit only allowing current to flow through the single use device when a negative voltage is provided on the common line.

2. The system of claim 1, wherein at least a portion of the common line, the one or more monitoring devices, the single use device and the activation circuit are located within a borehole penetrating the earth.

3. The system of claim 1, wherein at least one of the one or more monitoring devices is a gauge.

4. The system of claim 1, wherein the single use device is a bridge expansion plug.

5. The system of claim 1, wherein the activation circuit includes a blocking diode having an anode coupled to the common line and a cathode coupled to the single use device.

6. The system of claim 1, wherein the activation circuit includes:
a transistor, wherein the transistor is configured to receive a gating signal from the single use device that causes the transistor to cause current to cease to flowing through the single use device to the common line.

7. The system of claim 6, wherein the activation further includes:
a fuse coupled between the common line and the transistor, the fuse configured to blow when the transistor receives the gating signal.

8. The system of claim 1, wherein the single use device is a first single use device, the activation circuit is a first activation circuit and further comprising:
a second single use device coupled to the common line;
a second activation circuit coupled between the second single use device and the common line, the second activation circuit only allowing current to flow through the second single use device when a negative voltage is presented on the common line.

9. The system of claim 8, wherein the first activation circuit includes a first blocking diode and the second activation circuit includes a second blocking diode and one or more zener diodes connected in series with the one or more zener diodes.

10. The system of claim 9, wherein the first activation circuit includes first fuse electrically disposed between the common line and the first blocking diode and the second activation circuit includes second fuse electrically disposed between the common line and the second blocking diode.

11. The system of claim 10, wherein at least one of the one or more monitoring devices is a gauge.

12. The system of claim 10, wherein the first single use device is a bridge expansion plug.

13. The system of claim 1, further comprising:
a power supply coupled to the common line, the power supply configured to provide both the positive voltage and the negative voltage.

14. A method comprising:
coupling one or more monitoring devices coupled to a common line, the one or more monitoring devices configured to operate when a positive voltage is provided on the common line;
a first activation circuit to the common line; and
coupling a first single use device to the first activation circuit such that a current from the first single use device to the common line when a negative voltage is provided on the common line.

15. The method of claim 14, further comprising:
providing the negative voltage on the common line; and
after providing the negative voltage, providing a positive voltage on the common line.

16. The method of claim 15, wherein the negative voltage is provided until the first single use device is electrically separated from the common line.

17. A system comprising:
a common line configured to conduct electrical power;
one or more monitoring devices coupled to the common line and configured to operate when a negative voltage is provided on the common line;
a single use device coupled to the common line;
an activation circuit coupled between the single use device and the common line, the activation circuit only allowing current to flow through the single use device when a positive voltage is provided on the common line.

18. The system of claim 17, wherein at least a portion of the common line, the one or more monitoring devices, the single use device and the activation circuit are located within a borehole penetrating the earth.

19. The system of claim 17, wherein at least one of the one or more monitoring devices is a gauge.
